(19) United States
(12) Patent Application Publication
(10) Pub. No.: US 2024/0112925 A1
(43) Pub. Date: Apr. 4, 2024

(54) BRUSHES, SYSTEMS, AND METHODS FOR DISPENSING MULTIPLE FLUIDS DURING CLEANING OF A SURFACE

(71) Applicant: Illinois Tool Works Inc., Glenview, IL (US)

(72) Inventors: Bradley Scott Withers, El Dorado Hills, CA (US); Corey Alan Hughes, Sacramento, CA (US)

(21) Appl. No.: 17/959,606

(22) Filed: Oct. 4, 2022

(51) Int. Cl. H01L 21/67; A46B 9/00; A46B 11/00; A46B 11/06; A46B 13/00; A46B 13/04; A46D 1/00; H01L 21/02

(52) U.S. Cl. CPC H01L 21/67046; A46B 9/005; A46B 11/0072; A46B 11/063; A46B 13/008; A46B 13/04; A46D 1/0207; H01L 21/02096; A46B 2200/3073

(57) ABSTRACT

A disclosed example brush for dispensing multiple fluids during cleaning of a surface includes: an annular porous polymeric brush body configured to dispense a first fluid through the brush; and a first annular plate mechanically coupled to the brush body, wherein the plate includes: a channel to direct the first fluid from an inlet of the channel to the brush body; and a plate annulus aligned with a brush annulus of the brush body, such that the brush annulus and the plate annulus direct a second fluid from an inlet to the surface.

### BACKGROUND

The present disclosure relates to substrate-cleaning brushes, and more particularly, to brushes, systems, and methods for dispensing multiple fluids during cleaning of a surface.

In the semiconductor manufacturing industry and other industries, brushes are used to remove contaminants from surfaces, such as from semiconductor wafers. Depending on the specific application, cleaning of a substrate or surface may also involve delivery of one or more substances (e.g., chemicals, ultra-pure water (UPW), deionized water (DIW), etc.) to the substrate or surface.

Limitations and disadvantages of conventional approaches to conditioning brushes will become apparent to one of skill in the art, through comparison of such approaches with some aspects of the present method and system set forth in the remainder of this disclosure with reference to the drawings.

### SUMMARY

Brushes, systems, and methods for dispensing multiple fluids during cleaning of a surface are disclosed, substantially as illustrated by and described in connection with at least one of the figures, as set forth more completely in the claims.

### BRIEF DESCRIPTION OF THE DRAWINGS

These and/or other aspects will become apparent and more readily appreciated from the following description of the exemplary embodiments, taken in conjunction with the accompanying drawings.

FIG. 1 is a schematic diagram of an example system to clean a substrate, involving dispensing of multiple fluids via a brush during cleaning of the substrate, in accordance with aspects of this disclosure.

FIGS. 2A and 2B are plan views of the brush and substrate of FIG. 1 during an example cleaning process.

FIG. 3 illustrates a top view of the example brush of FIG. 1.

FIG. 4 illustrates a bottom view of an example brush of FIGS. 1 and 3.

FIG. 5 illustrates an example dispensation of multiple fluids during operation of the example system and brush of FIGS. 1-4.

FIG. 6 is a schematic diagram of another example system, including another example brush, to clean a surface during a cleaning process, in accordance with aspects of this disclosure.

FIG. 7 illustrates a bottom view of the example brush of FIG. 6.

FIGS. 8A-8D illustrate other example brushes including protrusions having different shapes, sizes, and/or distributions over the bottom surface of the brush.

FIG. 9 illustrates a flowchart representative of an example method which may be performed using the example systems and/or brushes of FIGS. 1-7 to clean a surface such as the substrate of FIGS. 1 and 6.

FIGS. 10A, 10B, and 10C are more detailed views of example nodules, which may be used to implement the brushes of FIGS. 1 and/or 6, including microtexturing.

The figures are not necessarily to scale. Where appropriate, similar or identical reference numbers are used to refer to similar or identical components.

### DETAILED DESCRIPTION

Various applications and processes may benefit from physical cleaning of a surface. For example, in semiconductor manufacturing, a semiconductor wafer may be cleaned to remove potentially destructive contaminants during one or more stages of fabricating electronic circuits on the wafer. The cleaning can be provided by, for example, a brush that comes in contact with the surface to be cleaned.

To efficiently clean a substrate, disclosed example brushes come into contact with a substrate to be cleaned in the presence of a cleaning chemical. Conventional brushes are either mounted or cast directly to rotatable hollow bases or mandrels, with holes that allow water, a chemical, or both to flow through the base or mandrel, into and through the brush body, and onto the substrate or wafer to be cleaned.

Due to the construction of conventional disk and roller brushes, conventional brushes are not capable of delivering multiple chemicals, or a chemical and water, to the substrate/wafer surface without passing the chemical and/or water through the brush material itself. While it can be beneficial to pass water (e.g., DIW, UPW) through the brush body material for the purposes of hydrodynamically dislodging process debris from the brush surface, it is generally not desirable to pass chemistry through the brush body material. Chemistries can react with the brush body material, which can result in alteration of the physical properties of the brush body material and ultimately lead to undesirable contact cleaning issues. Polyvinyl acetal (PVA) is a highly absorbent, porous polymer which may be used as a brush body material. Due to the absorbent and porous nature of PVA, It is difficult to remove and/or displace the chemistry from the PVA material (e.g., by rinsing) after the chemistry has been applied. Furthermore, the integrity of the (ultra pure) water delivery system is also compromised whenever chemical is dispensed from the same hollow base/mandrel flow cavity and/or through the same flow path. For these reasons, conventional brush systems apply process chemistry, especially pertaining to post-chemical mechanical planarization (post-CMP) cleaning applications, directly to the substrate or wafer surface to be cleaned, while the hollow base/mandrel flow channel is typically reserved for water.

However, the fixed application of chemistry directly to the substrate or wafer surface in conventional systems does not permit the chemical to be dispensed directly to the wafer or substrate center because the brush blocks chemical delivery to the substrate/wafer center. In many cleaning applications, including post-CMP, the substrate/wafer is also rotated during the process to maximize exposure of the PVA brush and chemistry to the cleaning surface. Centrifugal forces naturally push the applied chemistry away from the center of the substrate/wafer, resulting in chemical deficiency at the center of the substrate/wafer.

Disclosed brushes, cleaning systems, and methods overcome the drawbacks of conventional cleaning systems by enabling delivery of multiple chemicals, or a chemical and water, to the surface of a substrate simultaneously. Example disc-shaped brushes include a porous polymeric brush body and one or more support plates. In some disclosed examples, a first process chemical is delivered through the annulus of the brush and support plate(s), and a second process chemical is delivered through the brush body. The plates provide structure to support the polymeric brush body and connect the brush to a support arm for movement and/or rotation of the brush. By dispensing multiple chemistries in this manner during the brush cleaning process, the distribution of the chemistries to the substrate/wafer is more uniform.

Example brushes may be configured with different geometries, including shaped nodules extending from the brush body to make contact with the surface. In some examples, the contact surfaces are configured with microtextures to achieve one or more tribological effects.

As used herein, chemicals or process chemicals may refer to any substance that may be applied via disclosed brushes, including water such as DIW and/or UPW.

Disclosed examples brushes for dispensing multiple fluids during cleaning of a surface include: an annular porous polymeric brush body configured to dispense a first fluid through the brush; and a first annular plate mechanically coupled to the brush body, wherein the plate includes: a channel to direct the first fluid from an inlet of the channel to the brush body; and a plate annulus aligned with a brush annulus of the brush body, such that the brush annulus and the plate annulus direct a second fluid from an inlet to the surface. In some examples, the brush is constructed via at least one of molding, machining, or additive manufacturing.

In some example brushes, the brush body is constructed via at least one of molding, machining, or additive manufacturing. In some example brushes, the brush body includes a plurality of protrusions extending from the brush body in a direction away from the first plate. In some example brushes, the protrusions include at least one of nodules or spokes. Some example brushes further include a second annular plate coupled to the brush body opposite the first plate.

In some example brushes, at least one of the first plate or the second plate is constructed via at least one of molding, machining, or additive manufacturing. In some example brushes, the first and second plates are mechanically coupled. In some example brushes, the second plate has a plurality of apertures, in which the protrusions on the brush body extend through the apertures toward the surface.

In some example brushes, the first plate is at least one of a polymeric material or a ceramic material. In some example brushes, the brush body is configured to disperse the first fluid from the channel through the brush body. In some example brushes, the brush body comprises polyvinyl acetal (PVA).

Disclosed example systems to dispense multiple fluids during cleaning of a surface include: a brush for dispensing multiple fluids during cleaning of a surface, the brush including: an annular brush body configured to dispense a first fluid through the brush; and a first annular plate mechanically coupled to the brush body, wherein the plate includes: a channel to direct the first fluid from an inlet of the channel to the brush body; and a plate annulus aligned with a brush annulus of the brush body, such that the brush annulus and the plate annulus direct a second fluid from an inlet to the surface; a support arm coupled to the first annular plate and configured to support and rotate the brush; a first fluid source configured to dispense the first fluid to the inlet of the channel; and a second fluid source configured to dispense the second fluid via the plate annulus and the brush annulus.

In some example systems, the brush body is constructed via at least one of molding, machining, or additive manufacturing. In some example systems, the brush body includes a plurality of protrusions extending from the brush body in a direction away from the first plate. In some example systems, the protrusions include at least one of nodules or spokes. Some example systems further include a second annular plate coupled to the brush body opposite the first plate.

In some example systems, at least one of the first plate or the second plate is constructed via at least one of molding, machining, or additive manufacturing. In some example systems, the first and second plates are mechanically coupled. In some example systems, the second plate has a plurality of apertures, in which the protrusions on the brush body extend through the apertures toward the surface.

Disclosed example methods to clean a surface involve positioning an annular brush in contact with a surface to be cleaned; rotating the brush; during the rotation, dispensing a first fluid to the surface by dispensing the first fluid to a first side of the brush for dispersal through the brush; and dispensing a second fluid to the surface via an annulus of the brush.

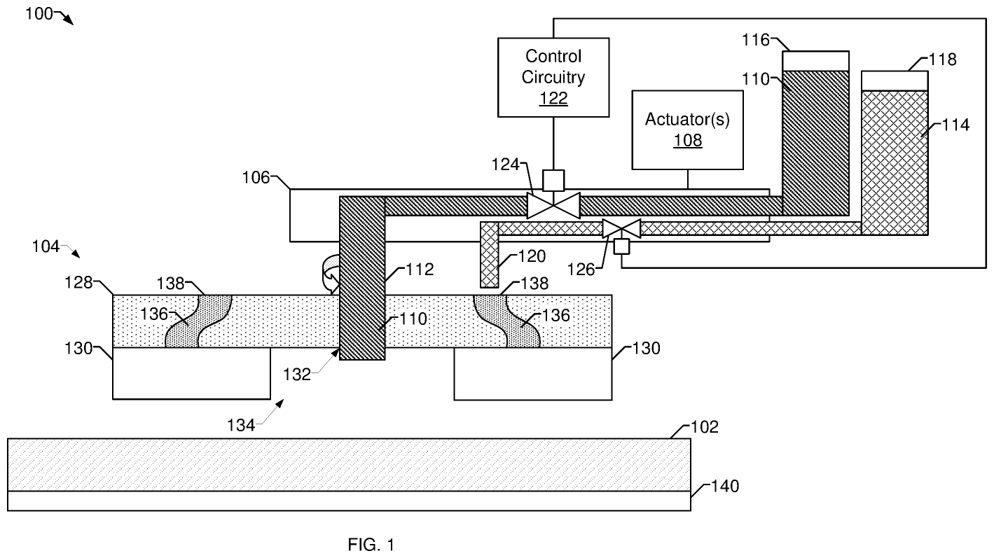

FIG. 1 is a schematic diagram of an example system 100 to clean a substrate 102, involving dispensing of multiple fluids via a brush 104 during cleaning of the substrate 102. The example system 100 includes a support arm 106 coupled to the brush 104. The support arm 106 positions the brush 104 relative to the substrate 102, and couples the brush 104 to one or more actuator(s) 108. The actuator(s) 108 move the brush 104 and/or rotate the brush 104 via the support arm 106 with respect to the substrate 102.

The system 100 and the brush 104 are capable of simultaneously delivering multiple fluids to the brush 104 and/or substrate 102 during cleaning. As described in more detail below, a first chemical 110 may be dispersed to the substrate 102 via a spindle 112, which couples the brush 104 to the support arm 106 (e.g., providing rotational torque to the brush 104 from the actuator(s) 108). A second chemical 114 may be simultaneously dispersed to the substrate 102 via the body of the brush 104, such as by dispersing the second chemical 114 through the brush 104.

The example system 100 includes a first reservoir 116, which stores the first chemical 110 and is in fluid communication with the spindle 112 for dispensing of the first chemical 110. The system 100 also includes a second reservoir 118, which stores the second chemical 114 and is in fluid communication with a dispenser 120 (e.g., a nozzle, a tube, etc.). The first and second reservoirs 116, 118 may have the same or different capacities. The first and second reservoirs 116, 118 may be local or proximate to the system 100 and/or may be facility-based supplies of pressurized chemicals 110, 116 in fluid communication with the support arm 106.

The system 100 includes control circuitry 122 configured to control valves 124, 126. The valves 124, 126 may be controlled to set dispensation rates for the chemicals 110, 114 from the reservoirs 116, 118. The example valves 124, 126 are low power, electronically controlled solenoid valves. However, any other type of electronically controlled valve may be used, taking into account the desired flow rates, power consumption, and/or response times.

The example brush 104 includes an annular plate 128 and an annular brush body 130. The annular plate 128 is attached or bonded to the annular brush body 130, and provides mechanical support and coupling between the brush body 130 and the spindle 112. The brush body 130 is placed into contact with the substrate 102 to clean and/or polish the substrate 102.

The example plate 128 includes an annulus 132. The spindle 112 extends through the annulus 132 to enable delivery of the first chemical 110 to the substrate 102 through the brush 104. The brush body 130 also includes an annulus 134, which is aligned (e.g., overlapping, concentric, etc.) with the annulus of the plate 128. The annuluses 132, 134 are sufficiently large to permit delivery of the first chemical 110 to the substrate 102. In some examples, the annulus 134 of the brush body 130 is sufficiently large to reduce or eliminate chemical interactions between the first chemical 110 and the second chemical 114 within the body of the brush body 130 prior to the chemicals 110, 114 reaching the substrate 102. The annulus 134 of the brush body 130 may also be sufficiently small to increase (e.g., maximize) contact area between the brush body 130 and the substrate 102.

The example brush body 130 is a porous polymeric foam, which may be molded, machined, constructed using additive manufacturing techniques, and/or otherwise constructed in an annular shape. Example polymeric foams that may be used to implement the brush body 130 include polyvinyl acetal foams, polyurethane foams, polyolefin foams, porous fluoropolymers, and/or silicone foams.

The plate 128 further includes one or more channel(s) 136, which extend from an inlet 138 of the channels 136 at a top side of the plate 128, to the interface between the plate 128 and the brush body 130. The channel(s) 136 provide fluid delivery from the nozzle 120 to the brush body 130. The nozzle 120 is aligned with the channel(s) 136 to deliver the second chemical 114 to the channel(s) 136. The channels 136 may operate as a secondary reservoir to provide the second chemical 114 directly to the brush body 130.

Because the example brush body 130 is porous, the second chemical 114 disperses through the brush body 130 toward the substrate 102, and eventually reaches the interface between the brush body 130 and the substrate 102 for cleaning. In some examples, the channels 136 are configured to provide substantially even dispersion of the second chemical 114 through the brush body 130, to provide different concentrations of the second chemical 114 at different locations within the brush body 130 or different locations on the surface of the brush body 130, or to focus dispensing of the second chemical 114 at one or more locations on the surface of the brush body 130.

The substrate 102 may be supported on a platen 140 or other support surface. In some examples, the substrate 102 is rotated by the platen 140 in a same or different rotational direction as the rotation of the brush 104 during the cleaning process. In other examples, the substrate 102 may be conveyed in a linear direction, with or without rotation of the substrate 102.

The example control circuitry 122 includes at least one controller or processor that controls the operations of the system 100. The control circuitry 122 receives and processes multiple inputs associated with the performance and demands of the system 100. The control circuitry 122 may include one or more microprocessors, such as one or more “general-purpose” microprocessors, one or more special-purpose microprocessors and/or ASIC S, and/or any other type of processing device. For example, the control circuitry 122 may include one or more digital signal processors (DSPs). The example control circuitry 122 may further include one or more storage device(s) (e.g., ROM, flash memory, a hard drive, and/or any other suitable optical, magnetic, and/or solid-state storage medium, and/or a combination thereof) and one or more memory device(s) (e.g., volatile and/or non-volatile memory).

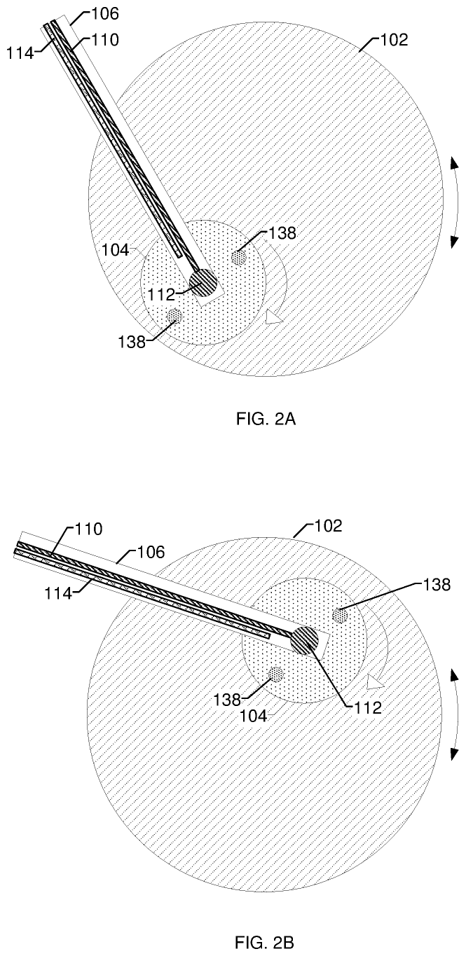

FIGS. 2A and 2B are plan views of the brush 104 and substrate 102 of FIG. 1 in different radial and/or angular positions over the surface of the substrate 102 during an example cleaning process. The example brush 104 is supported, positioned, and rotated via the support arm 106. The support arm 106 also delivers the chemicals 110, 114 to the brush 104 (e.g., to the annulus 132, 134 of the brush 104, to the inlets 138 channels 136).

The example substrate 102 may rotate in either direction, or remain stationary, while the support arm 106 moves the brush 104 over the surface of, and in contact with, the substrate 102. The support arm 106 further controls rotation of the brush 104 via the spindle 112. The radial position of the brush 104 on the substrate 102 is controlled by moving the support arm 106 with respect to the substrate 102, while the angular position of the brush 104 with respect to the surface of the substrate 102 is controlled by rotating the substrate 102. However, in other examples, the support arm 106 may be capable of positioning the brush 104 at any angular and/or radial position on the substrate 102. The support arm 106 may further control the distance between the brush 104 and the substrate 102, and/or the pressure applied to the substrate 102 by the brush 104.

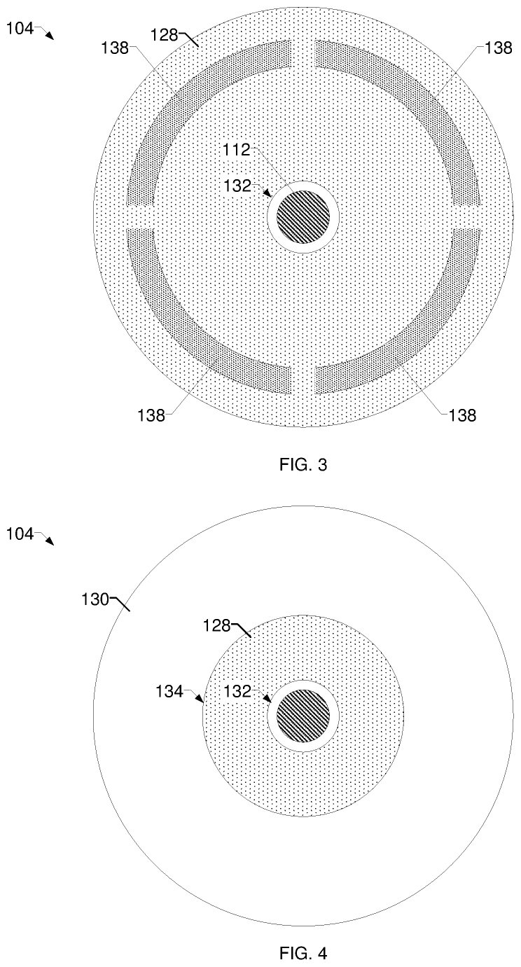

FIG. 3 illustrates a top view of the example brush 104 of FIG. 1. The brush 104 includes the top plate 128, which mechanically couples the brush 104 to the spindle 112. The first channels 136 are located in an interior of the top plate 128, with the inlets 138 extending around a circumference of the top plate 128.

The top plate 128 may bridge the channels 136 or inlets 138 at positions to couple the inner and outer radial portions of the top plate 128. The channels 136 may take any desired shape, including shapes, quantities, and/or sizes of the inlets 138 and/or shapes, quantities, and/or sizes of interfaces with the brush body 130 to achieve the desired dispersion of the second chemical 114 from the channel(s) 136 to the substrate 102 via the brush body 130.

FIG. 4 illustrates a bottom view of an example brush 104 of FIGS. 1 and 3. As illustrated in FIG. 4, the brush body 130 includes an annulus 134 that is concentric with an annulus 132 of the top plate 128 and/or concentric with the spindle 112. The brush body 130 is mechanically attached to the top plate 128, such as by fasteners, chemical bonding, adhesion, overmolding, and/or any other attachment techniques. The top plate 128 and the brush body 130 may be constructed by at least one of molding, machining, additive manufacturing (e.g., three-dimensional printing), and/or any other manufacturing techniques, either separately or in combination. The example top plate 128 is a polymeric material, such as polyethylene terephthalate (PET), polyether ether ketone (PEEK), perfluoroalkoxy alkane (PFA), polytetrafluoroethylene (PTFE), and/or any other material, such as a ceramic material, which is compatible with the chemical environment for which it is being used.

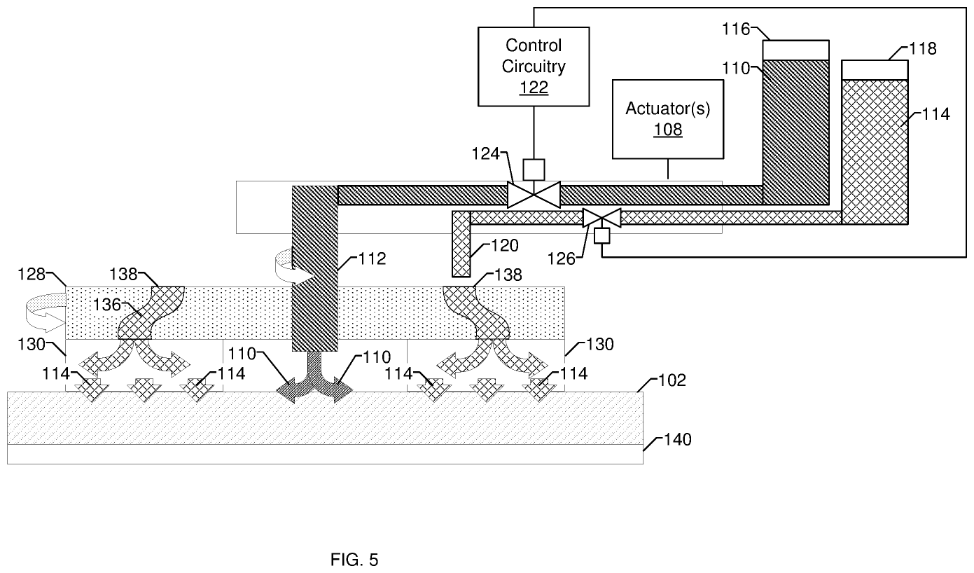

FIG. 5 illustrates an example dispensation of multiple fluids (e.g., chemicals 110, 114) during operation of the example system 100 and brush 104 of FIGS. 1-4. As illustrated in FIG. 5, the second chemical 114 is dispensed from the nozzle 120 to the inlets 138 of the channels 136. The channels 136 direct the second chemical 114 to the brush body 130. Due to the porous nature of the example brush body 130, the second chemical 114 disperses through the brush body 130, and is eventually dispensed toward the substrate 102. The rate of dispensation of the second chemical 114 may be dependent on the flow rate controlled by the control circuitry 122 via the valve 126, the rotational speed of the brush 104, pressure between the brush body 130 and the substrate 102, and/or other factors. Rotation of the substrate 102 may cause the first chemical 110 and/or the second chemical 114 to be urged radially outward with respect to the substrate 102 upon deposition of the chemical(s) 110, 114 onto the surface of the substrate 102.

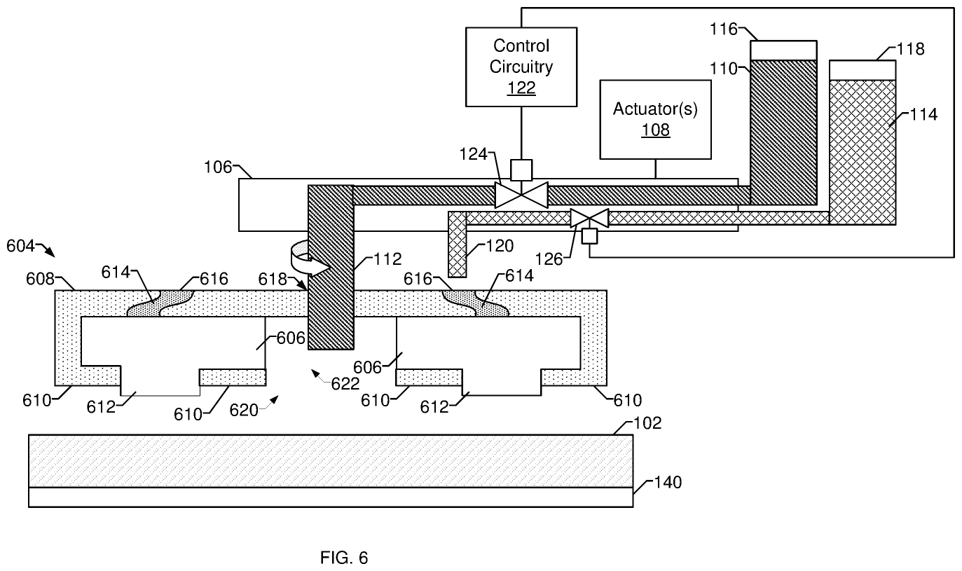

FIG. 6 is a plan view of another example system 600 to clean the substrate 102 during a cleaning process, including another example brush 604. The example system 600 includes the support arm 106, the actuator(s) 108, the spindle 112, the reservoirs 116, 118, the nozzle 120, the control circuitry 122, the valves 124, 126, and the platen 140 of FIGS. 1-5 described above.

The example brush 604 of FIG. 6 includes a brush body 606, a top plate 608, and a bottom plate 610. The top plate 608 may be similar or identical to the top plate 128 of FIGS. 1-5. In the example of FIG. 6, the top plate 608 and the bottom plate 610 are connected to provide top and bottom support to the brush body 606. In other examples, the top plate 608 and the bottom plate 610 may be separately connected to the brush body 606 to provide rigidity and/or control chemical dispensation from the brush body 606.

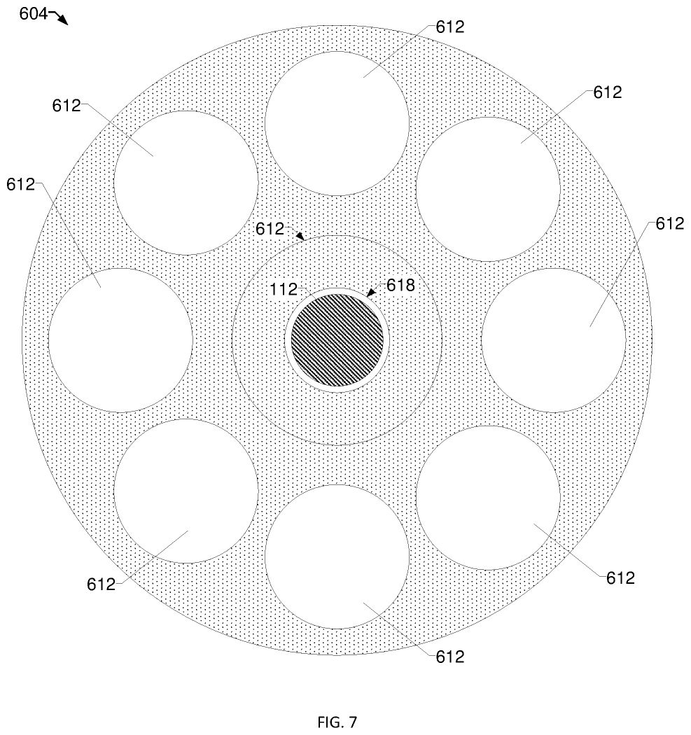

FIG. 7 illustrates a bottom view of the example brush of FIG. 6. The brush body 606 of FIG. 6 includes protrusions 612, such as nodules, that extend through the bottom plate 610 to contact the substrate 102. The shapes of the protrusions 612 may be controlled to control the contact pressure (contact area) on the substrate 102 and/or the locations and/or rates of dispensation of the second chemical 114 to the substrate 102. The protrusions 612 extend through corresponding apertures in the bottom plate 610, and the bottom plate 610 supports a remainder of the brush body 606.

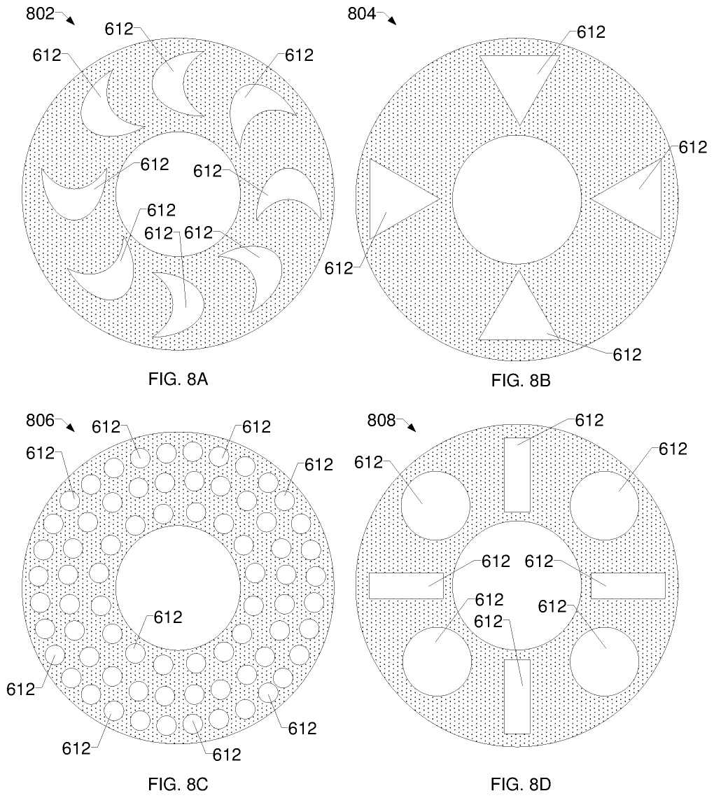

FIG. 7 illustrates example circular-shaped protrusions 612, and FIGS. 8A-8D illustrate other example brushes 802, 804, 806, 808 including protrusions 612 having different shapes, sizes, and/or distributions over the bottom surface of the brush. While the example brushes 604, 802-808 include the respective bottom plates 610, in other examples the brush may include protrusions or nodules while omitting the bottom plate 610.

The top plate 608 includes channels 614 having inlets 616. The channels 614 and inlets 616 may be similar or identical to the example channels 136 and inlets 138 of the brush 104 of FIGS. 1-5. However, as discussed above, the channels 614 and/or inlets 616 may have and desired shape, size, and/or quantity to receive, disperse, and dispense the second chemical 114 to the substrate 102. As shown in FIG. 7, an annulus 618 of the top plate 608 is concentric with an annulus 620 of the bottom plate 610 and an annulus 622 of the brush body 606, and allows delivery of the first chemical 110 to the substrate 102 via the spindle 112.

While the foregoing examples include one or more plates on the exterior of the porous polymeric brush body, in some other examples the brush body is overmolded or printed over an interior plate or other structure. In some such examples, the interior plate or structure implements the channels, inlets, and/or interfaces with the brush body to disperse the second chemical 114 from the nozzle 120. The interior plate or structure may include, and/or be configured to connect to, the spindle 112 for actuation of the brush and dispensation of the first chemical 110 via an annulus in the porous polymeric brush body.

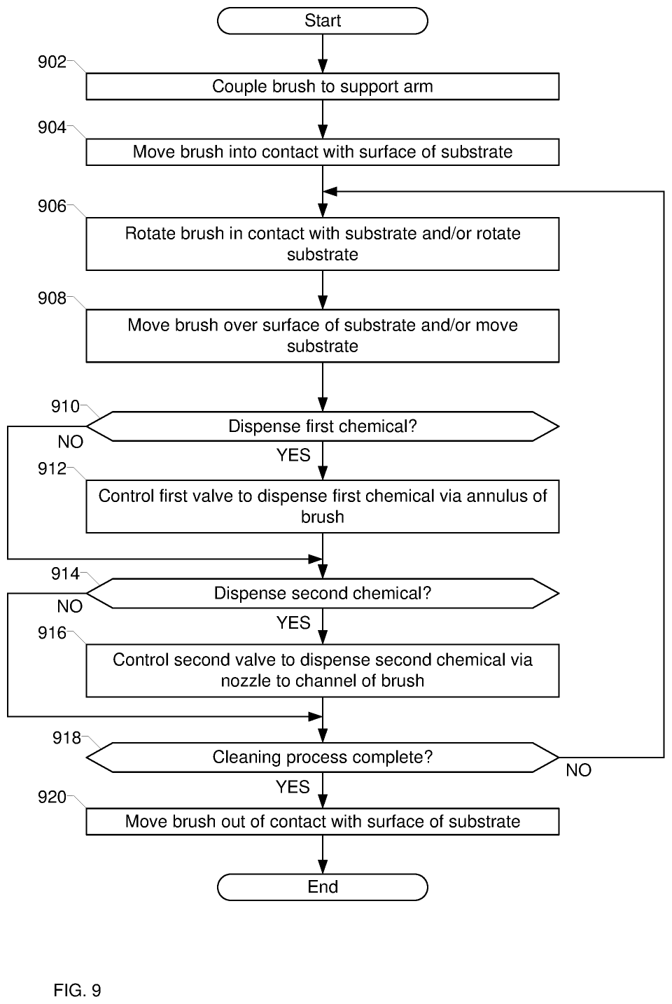

FIG. 9 illustrates a flowchart representative of an example method 900 which may be performed using the example systems 100, 600 and/or brushes 104, 604 of FIGS. 1-7 to clean a surface (e.g., the substrate 102).

At block 902, the brush 104, 604 is coupled to a support arm, such as the example support arm 106 of FIGS. 1-7. For example, a top plate 128, 608 and/or a bottom plate 610 of the brush 104, 604 may be connected to the spindle 112 for support, movement, and/or rotation of the brush 104, 604 with respect to the substrate 102.

At block 904, the support arm 106 moves the brush 104, 604 into contact with the surface of the substrate 102. The support arm 106 may determine a pressure at which the brush 104 is placed into contact with the substrate 102. At block 906, the support arm 106 rotates the brush in contact with the substrate 102, and/or the substrate 102 is rotated (e.g., via the platen 140). At block 908, the support arm 106 moves the brush 104, 604 over the surface of the substrate 102, and/or the substrate 102 is moved (e.g., via a conveyor, stage, or other planar movement system). By way of blocks 906 and 908, the brush body 130 and/or brush nodules 612 scrub, polish, and/or otherwise clean the substrate 102. The control circuitry 122 may, in addition to controlling the valves 124, 126, control the actuator(s) 108 to control the support arm 106.

At block 910, the control circuitry 122 determines whether to dispense the first chemical 110 (e.g., from the first reservoir 116 via a nozzle in the spindle 112). For example, the control circuitry 122 may determine whether a recipe or other cleaning procedure specifies a timing, frequency, and/or amount for delivery of the first chemical 110 during cleaning. If the control circuitry 122 determines that the first chemical 110 is to be dispensed (block 910), at block 912 the control circuitry 122 controls the first valve 124 to dispense the first chemical 110 to the substrate 102 via the annulus of the brush body 130. For example, the control circuitry 122 may control the first valve 124 to dispense a specified amount, and/or receive feedback from one or more flow sensors to measure the dispensed amount.

At block 914, the control circuitry 122 determines whether to dispense the second chemical 114 (e.g., from the second reservoir 118 via the nozzle 120). For example, the control circuitry 122 may determine whether a recipe or other cleaning procedure specifies a timing, frequency, and/or amount for delivery of the second chemical 114 during cleaning. If the control circuitry 122 determines that the second chemical 114 is to be dispensed (block 914), at block 916 the control circuitry 122 controls the second valve 126 to dispense the first chemical 114 to the substrate 102 via the channel 136 and the brush body 130, 606 and/or the nodules 612. For example, the control circuitry 122 may control the second valve 126 to dispense a specified amount, and/or receive feedback from one or more flow sensors to measure the dispensed amount. The first and second chemicals 110, 114 may be dispensed sequentially and/or simultaneously, depending on the particular cleaning procedure.

At block 918, the control circuitry 122 determines whether the cleaning process is complete. If the cleaning process is not complete (block 918), control returns to block 906 to continue rotating and/or moving the brush, and/or dispensing the first and second chemicals 110, 114.

When the cleaning process is complete (block 918), at block 920 the control circuitry 122 controls the support arm 106 to move the brush 104, 604 out of contact with the surface of the substrate 102. The example method 900 then ends.

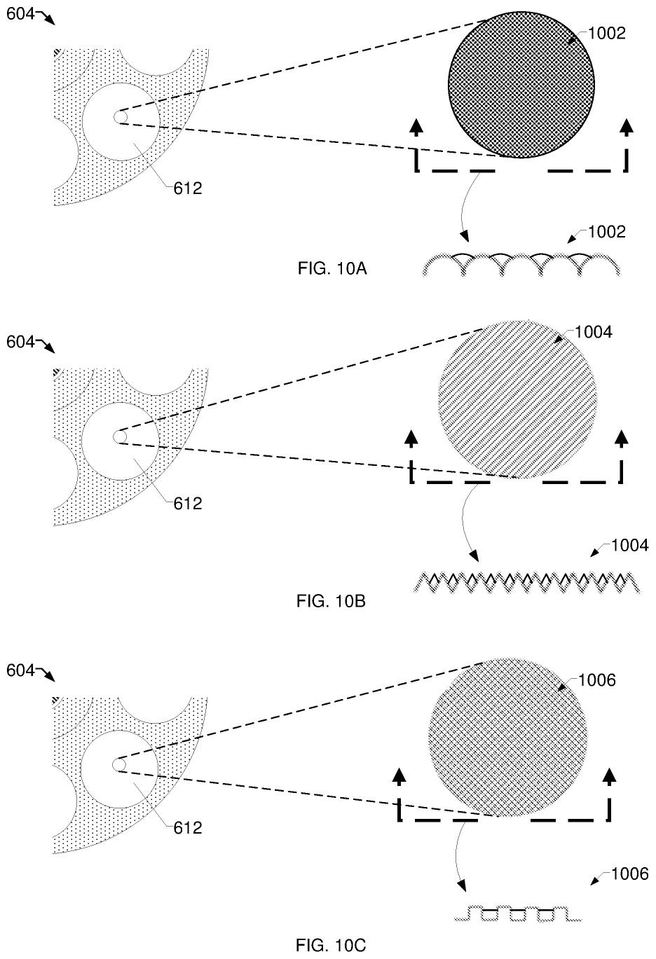

FIGS. 10A, 10B, and 10C are more detailed views of example surfaces 1002, 1004, 1006 of the brush body 130, 606 of the brushes 104, 604 of FIGS. 1 and/or 6. The example surfaces 1002, 1004, 1006 are formed with microtexturing, which can be applied to the surface of the brush body 130, 606 (e.g., to the surface of the nodules 612) to affect the cleaning action of the brush 104, 604 on the substrate 102. The microtexturing of the brush body 130, 606 may be performed during molding of the brush body 130, 606, by machining the brush body 130, 606, and/or using any other method of construction or modification.

FIG. 10A illustrates a plan view and an elevation view of an example surface 1002 of one of the nodules 612 of FIG. 6. The example surface 1002 has microtexturing including repeating rounded surfaces or microfeatures in a substantially constant pattern. FIG. 10B illustrates a plan view and an elevation view of an example surface 1004 of one of the nodules 612 of FIG. 6. The example surface 1004 has microtexturing including pointed surfaces or microfeatures in a substantially constant pattern. FIG. 10C illustrates a plan view and an elevation view of an example surface 1004 of one of the nodules 612 of FIG. 6. The example surface 1006 has microtexturing including flat, stepped surfaces or microfeatures in a substantially constant pattern.

While example microtextures and patterns are illustrated in FIGS. 10A-10C, the microfeature shapes, concentrations or densities of features, microfeature sizes, microfeature depths, and/or any other geometrical aspect of the microfeatures may be modified to obtain the desired cleaning effects, unique tribological functions (e.g., enhanced lubrication, increased friction, improved cleaning efficiency), and/or different dispensation effects of the second chemical 114. Different portions of the brush body 130, 606 and/or different nodules 612 may have different microtexturing features or properties. The same or different microtexturing may be used with different shapes of the nodules of FIGS. 8A-8D. The features and/or properties of the microtexturing may be selected based on the types of the first and/or second chemicals 110, 114 to be used during the cleaning process, such as to promote or mitigate intermixing of the first and/or second chemicals 110, 114 on the surface of the substrate 102.

The present methods and systems may be realized in hardware, software, and/or a combination of hardware and software. The present methods and/or systems may realize, for example, the control circuitry 122 in a centralized fashion in at least one computing system, or in a distributed fashion where different elements are spread across several interconnected computing systems. Any kind of computing system or other apparatus adapted for carrying out the methods described herein is suited. A typical combination of hardware and software may include a general-purpose computing system with a program or other code that, when being loaded and executed, controls the computing system such that it carries out the methods described herein. Another typical implementation may comprise one or more application specific integrated circuit or chip. Some implementations may comprise a non-transitory machine-readable (e.g., computer readable) medium (e.g., FLASH memory, optical disk, magnetic storage disk, or the like) having stored thereon one or more lines of code executable by a machine, thereby causing the machine to perform processes as described herein. As used herein, the term “non-transitory machine-readable medium” is defined to include all types of machine readable storage media and to exclude propagating signals.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or.” As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, the present method and/or system are not limited to the particular implementations disclosed. Instead, the present method and/or system will include all implementations falling within the scope of the appended claims, both literally and under the doctrine of equivalents.

What is claimed is:

1. A brush for dispensing multiple fluids during cleaning of a surface, the brush comprising:
an annular porous polymeric brush body configured to dispense a first fluid through the brush; and
a first annular plate mechanically coupled to the brush body, wherein the plate comprises:
a channel to direct the first fluid from an inlet of the channel to the brush body; and
a plate annulus aligned with a brush annulus of the brush body, such that the brush annulus and the plate annulus direct a second fluid from an inlet to the surface.

2. The brush of claim 1, wherein the brush body is constructed via at least one of molding, machining, or additive manufacturing.

3. The brush of claim 1, wherein the brush body comprises a plurality of protrusions extending from the brush body in a direction away from the first plate.

4. The brush of claim 3, wherein the protrusions comprise at least one of nodules or spokes.

5. The brush of claim 3, further comprising a second annular plate coupled to the brush body opposite the first plate.

6. The brush of claim 5, wherein at least one of the first plate or the second plate is constructed via at least one of molding, machining, or additive manufacturing.

7. The brush of claim 5, wherein the first and second plates are mechanically coupled.

8. The brush of claim 5, wherein the second plate comprises a plurality of apertures, the protrusions on the brush body extending through the apertures toward the surface.

9. The brush of claim 1, wherein the first plate comprises at least one of a polymeric material or a ceramic material.

10. The brush of claim 1, wherein the brush body is configured to disperse the first fluid from the channel through the brush body.

11. The brush of claim 1, wherein the brush body comprises polyvinyl acetal (PVA).

12. A system to dispense multiple fluids during cleaning of a surface, the system comprising:
a brush for dispensing multiple fluids during cleaning of a surface, the brush comprising:
an annular brush body configured to dispense a first fluid through the brush; and
a first annular plate mechanically coupled to the brush body, wherein the plate comprises:
a channel to direct the first fluid from an inlet of the channel to the brush body; and
a plate annulus aligned with a brush annulus of the brush body, such that the brush annulus and the plate annulus direct a second fluid from an inlet to the surface;
a support arm coupled to the first annular plate and configured to support and rotate the brush;
a first fluid source configured to dispense the first fluid to the inlet of the channel; and
a second fluid source configured to dispense the second fluid via the plate annulus and the brush annulus.

13. The system of claim 12, wherein the brush body is constructed via at least one of molding, machining, or additive manufacturing.

14. The system of claim 12, wherein the brush body comprises a plurality of protrusions extending from the brush body in a direction away from the first plate.

15. The system of claim 14, wherein the protrusions comprise at least one of nodules or spokes.

16. The system of claim 14, further comprising a second annular plate coupled to the brush body opposite the first plate.

17. The system of claim 16, wherein at least one of the first plate or the second plate is constructed via at least one of molding, machining, or additive manufacturing.

18. The system of claim 15, wherein the first and second plates are mechanically coupled.

19. The system of claim 15, wherein the second plate comprises a plurality of apertures, the protrusions on the brush body extending through the apertures toward the surface.

20. A method to clean a surface, the method comprising:
positioning an annular brush in contact with a surface to be cleaned;
rotating the brush;
during the rotation, dispensing a first fluid to the surface by dispensing the first fluid to a first side of the brush for dispersal through the brush; and
dispensing a second fluid to the surface via an annulus of the brush.
